(19) United States
(12) Patent Application Publication
(10) Pub. No.: US 2022/0167527 A1
(43) Pub. Date: May 26, 2022

(54) TEMPERATURE CORRECTION METHOD AND COMPUTER DEVICE IMPLEMENTING THE SAME

(71) Applicant: MITAC COMPUTING TECHNOLOGY CORPORATION, Taoyuan City (TW)

(72) Inventors: Yen-Chen CHEN, Taoyuan City (TW); Chien-Wei LIAO, Taoyuan City (TW); Pi-Ming LIU, Taoyuan City (TW)

(21) Appl. No.: 17/454,767

(22) Filed: Nov. 12, 2021

(30) Foreign Application Priority Data
Nov. 20, 2020 (TW) 109140835

(51) Int. Cl. H05K 7/20; G06F 1/20

(52) U.S. Cl. CPC H05K 7/20209; G06F 1/206

(57) ABSTRACT

A temperature correction method is provided for detecting a temperature of a computer device that includes a first ambient temperature sensor and a second ambient temperature sensor that are spaced apart from each other, and a fan module. When a temperature difference between the temperatures sensed by the first and second ambient temperature sensors is greater than a predetermined threshold value, a controller of the computer device performs temperature correction that is related to the temperature difference, a fan speed of the fan module, and at least one of the sensed temperatures.

### CROSS-REFERENCE TO RELATED APPLICATION

This application claims priority of Taiwanese Invention Patent Application No. 109140835, filed on Nov. 20, 2020.

### FIELD

The disclosure relates to a correction method, and more particularly to a method for correcting an ambient temperature measured for a computer device.

### BACKGROUND

In a conventional server, an ideal location to place an ambient temperature sensor should be inside the server and as far away from all heat generating components as possible. Therefore, the ambient temperature sensor is usually placed at a front edge of the conventional server, which is the closest location to the casing for setting up input and output ports, such as being placed at a front input/output (FIO) module of the conventional server, in order to avoid the influence of other heat generating components on the mainboard, which may further affect cooling control of the conventional server. Because of the market demand, a front edge of a server is usually designed to have a universal serial bus (USB) port that facilitates software update and/or system maintenance. Since there is only limited space at the front edge of a server, the FIO module is usually designed to have both of the USB port and the ambient temperature sensor. When the USB port is used such as when a USB flash drive is inserted in the USB port or when other devices are connected to the USB port for communication with the server, the USB port may heat up the FIO module, so the temperature sensed by the ambient temperature sensor that is placed at the FIO module of the conventional server may be higher than the actual ambient temperature. The higher sensed temperature may cause a controller to increase a fan speed of a fan module of the server, resulting in additional and unnecessary power consumption.

### SUMMARY

Therefore, an object of the disclosure is to provide a temperature correction method that can alleviate at least one of the drawbacks of the prior art.

According to the disclosure, the temperature correction method is implemented by a computer device that includes a first ambient temperature sensor, a second ambient temperature sensor spaced apart from the first ambient temperature sensor, and a fan module disposed to reduce a temperature within the computer device, and comprises steps of: A) by the first ambient temperature sensor, sensing a temperature nearby the first ambient temperature sensor; B) by the second ambient temperature sensor, sensing a temperature nearby the second ambient temperature sensor; C) by a controller of the computer device, reading the temperature sensed by the first ambient temperature sensor to generate a first ambient temperature value, reading the temperature sensed by the second ambient temperature sensor to generate a second ambient temperature value, and determining whether a temperature difference between the first ambient temperature value and the second ambient temperature value is greater than a predetermined threshold value; and D) by the controller, upon determining that the temperature difference is greater than the predetermined threshold value, using a temperature correction model to calculate a corrected ambient temperature value based on a current fan speed of the fan module, the temperature difference, and at least one of the first ambient temperature value or the second ambient temperature value.

Another object of the disclosure is to provide a computer device that implements the temperature correction method.

According to the disclosure, the computer device includes a first ambient temperature sensor, a second ambient temperature sensor, a controller and a fan module. The first ambient temperature sensor is configured to sense a temperature nearby the first ambient temperature sensor. The second ambient temperature sensor is spaced apart from the first ambient temperature sensor, and is configured to sense a temperature nearby the second ambient temperature sensor. The controller is electrically coupled to the first ambient temperature sensor for reading the temperature sensed thereby to generate a first ambient temperature value, is electrically coupled to the second ambient temperature sensor for reading the temperature sensed thereby to generate a second ambient temperature value, and is configured to determine whether a temperature difference between the first ambient temperature value and the second ambient temperature value is greater than a predetermined threshold value. The fan module is electrically coupled to the controller and is disposed to reduce a temperature within the computer device. The controller is further configured to, upon determining that the temperature difference is greater than the predetermined threshold value, using a temperature correction model to calculate a corrected ambient temperature value based on a current fan speed of the fan module, the temperature difference, and at least one of the first ambient temperature value or the second ambient temperature value.

### BRIEF DESCRIPTION OF THE DRAWINGS

Other features and advantages of the disclosure will become apparent in the following detailed description of the embodiment(s) with reference to the accompanying drawings, of which:

FIG. 1 is a block diagram illustrating a computer device that implements an embodiment of a temperature correction method according to the disclosure;

FIG. 2 is a schematic diagram illustrating part of a front input/output (FIO) module of the computer device;

FIG. 3 is an exploded front view the FIO module;

FIG. 4 is an exploded rear view of the FIO module;

FIG. 5 is a flow chart illustrating steps of the embodiment; and

FIG. 6 is a plot exemplarily illustrating a temperature correction model.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

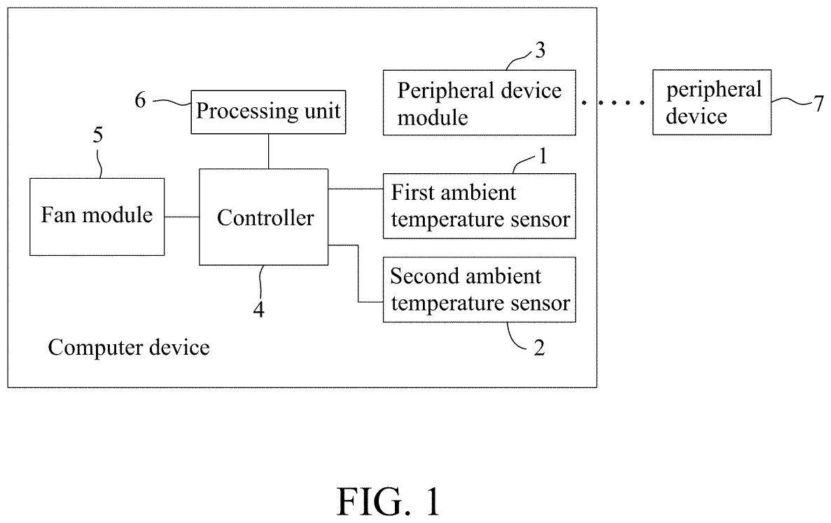

Referring to FIG. 1, an embodiment of a computer device that is capable of performing temperature correction according to this disclosure is shown to include at least two ambient temperature sensors. When a difference between the temperature values sensed by the ambient temperature sensors is greater than a predetermined threshold value, the computer device performs temperature correction that is related to the difference in temperature and a fan speed of a fan module of the computer device. In this embodiment, the computer device is exemplified as a server that includes two ambient temperature sensors, but this disclosure is not limited in this respect.

In detail, the computer device includes a first ambient temperature sensor 1, a second ambient temperature sensor 2, a peripheral device module 3 that is used for connection with a peripheral device 7, a controller 4 that is electrically connected to the first and second ambient temperature sensors 1, 2, a fan module 5 that is electrically connected to and controlled by the controller 4, a processing unit 6. The first ambient temperature sensor 1 and the second ambient temperature sensor 2 are spaced apart from each other. In some embodiments, the first ambient temperature sensor 1 and the second ambient temperature sensor 2 are disposed on different parts of the peripheral device module 3. In some embodiments, the first ambient temperature sensor 1 and the second ambient temperature sensor 2 are disposed on different parts of the computer device. For example, the first ambient temperature sensor 1 may be located on the peripheral device module 3, and the second ambient temperature sensor 2 is located not on the peripheral device module 3 and may for example be located on a housing (not shown) of the computer device. The peripheral device 7 that is to be connected to the peripheral device module 3 may be either a component that generates heat during operation, or a component that does not generate heat during operation. The predetermined threshold value is defined to be not smaller than the difference between the temperature values sensed by the first and second ambient temperature sensors 1, 2 when the peripheral device 7 that does not generate heat is connected to the peripheral device module 3 and is in operation, or when no device is connected to the peripheral device module 3. The processing unit 6 may execute an operating system or a basic input/output system (BIOS) and be realized as a central processing unit (CPU), a system on a chip (SoC) or a chipset that is composed of a CPU and a platform controller hub (PCH), multiple processors that are integrated as a single chip, an SoC or a chipset that is composed of multiple processors, an SoC or a chipset that is composed of multiple processors and a PCH, etc. The peripheral device 7 may be, for example but not limited to, a universal serial bus (USB) flash drive, a printer, a display, etc., and is exemplified as a USB flash drive in this embodiment. In this embodiment, the peripheral device module 3 is exemplified as a front input/output (FIO) module 3 that is used to establish connection between peripheral devices and the computer device. The controller 4 may be, for example but not limited to, a baseboard management controller (BMC), a microcontroller, a complex programmable logic device (CPLD), etc., and is exemplified as a BMC in this embodiment.

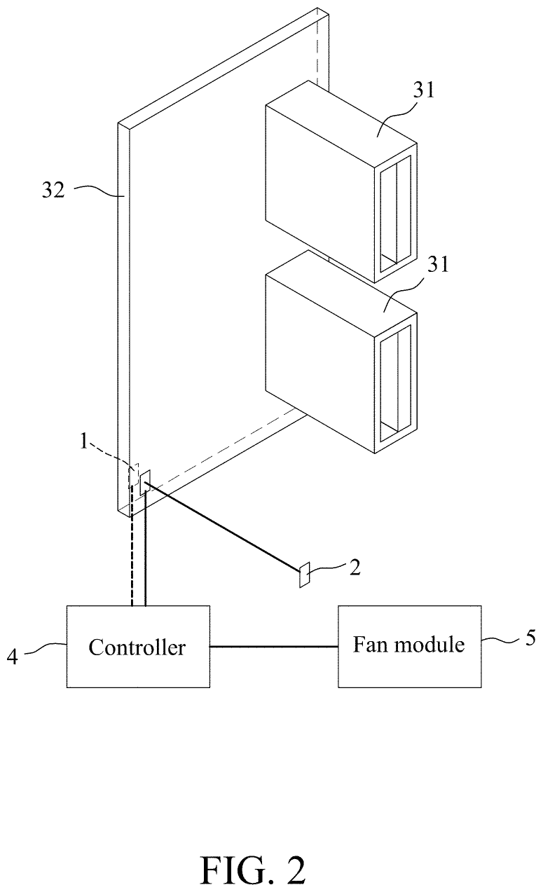

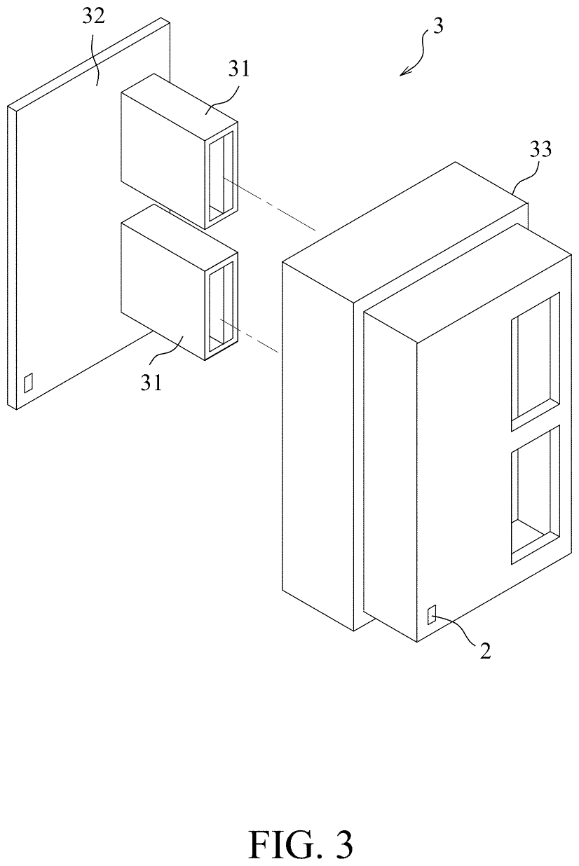

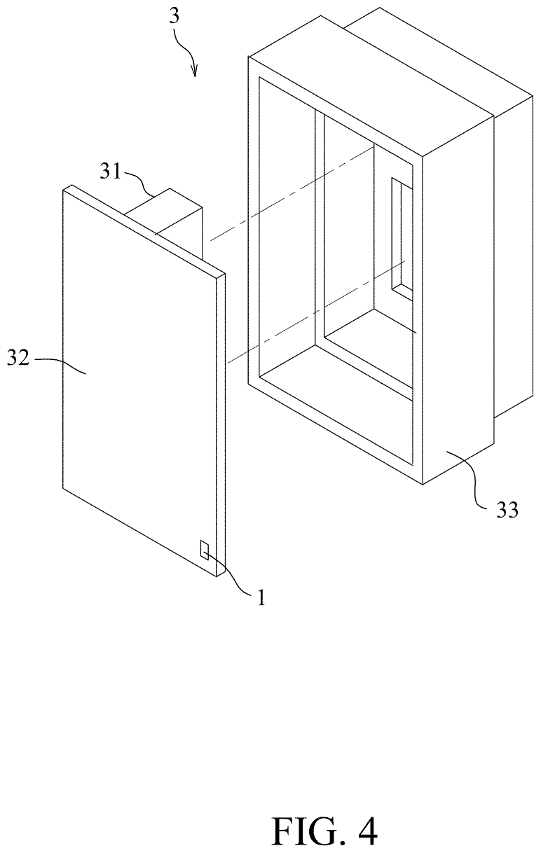

Referring to FIGS. 2, 3 and 4, the FIO module 3 includes at least one electronic component 31, a circuit board 32 on which the at least one electronic component 31 is located, and a casing 33 that accommodates the at least one electronic component 31 and the circuit board 32 therein. The circuit board 32 may be, for example but not limited to, an expansion board, a mainboard, etc., and is exemplified as an expansion board in this embodiment. The at least one electronic component 31 is exemplified as one or more input/output (IO) port 31, such as serial port(s), digital visual interface (DVI) port(s), USB port(s), and is exemplified as two USB ports 31 in this embodiment. Particularly, for each of the at least one electronic component 31 (which may be plural), the at least one electronic component 31 may be closer to the first ambient temperature sensor 1 than the at least one electronic component is to the second ambient temperature sensor 2 (i.e., a distance between one of the at least one electronic component 31 and the first ambient temperature sensor 1 is smaller than a distance between the same one of the at least one electronic component 31 and the second ambient temperature sensor 2). In some embodiments, the first and second ambient temperature sensors 1, 2 may both be placed on the circuit board 32. In the illustrative embodiment, the first ambient temperature sensor 1 is located on the circuit board 32 of the FIO module 3, and is configured to sense a temperature nearby the first ambient temperature sensor 1, and the controller 4 reads the temperature sensed by the first ambient temperature sensor 1 to generate a first ambient temperature value. When a USB flash drive is inserted into one of the USB ports 31 to operate, the USB flash drive, the USB port 31, and relevant circuits may generate heat and thus raise a temperature of the FIO module 3 by virtue of heat conduction. As a result, a temperature sensed by the first ambient temperature sensor 1 that is also located on the circuit board 32 may be higher than an actual ambient temperature within the computer device (e.g., an average of temperatures measured at multiple positions in the computer device, a temperature within the computer device measured at a position that is distant from a processor of the computer device, etc.). The second ambient temperature sensor 2 is spaced apart from the circuit board 32 and is configured to sense a temperature nearby the second ambient temperature sensor 2, and the controller 4 reads the temperature sensed by the second ambient temperature sensor 2 to generate a second ambient temperature value. Since the second ambient temperature sensor 2 is away from the USB flash drive and the USB ports 31 (which may be heated up because of signal or power transmission between the computer device and the USB flash drive), such as being located on another circuit board (not shown) or the casing 33, the temperature sensed by the second ambient temperature sensor 2 (i.e., the second ambient temperature value) would be less affected by the heat conduction effect and would be closer to the actual ambient temperature as compared to that sensed by the first ambient temperature sensor 1 (i.e., the first ambient temperature value).

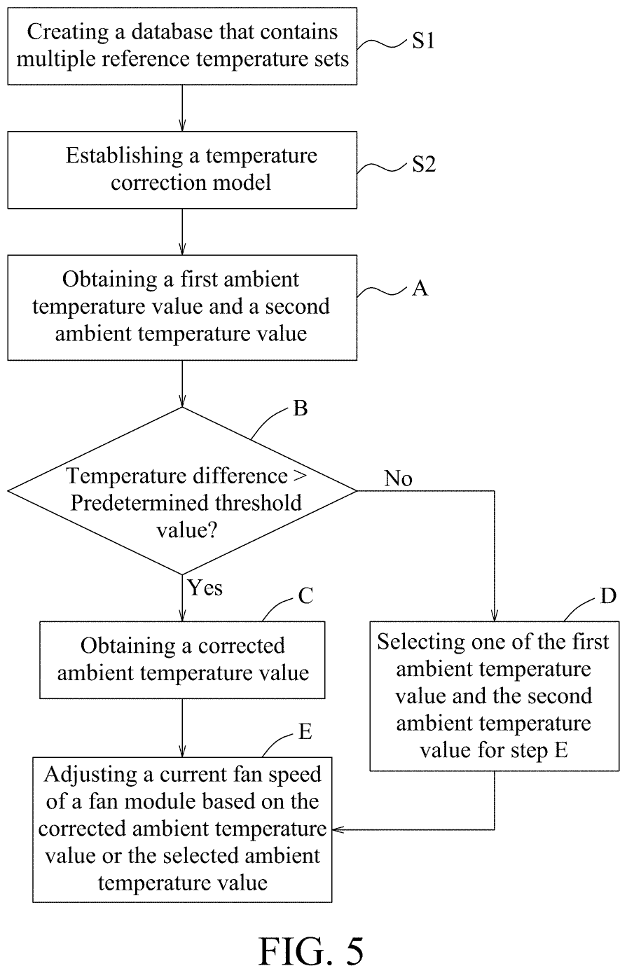

FIG. 5 is a flow chart illustrating an embodiment of a temperature correction method implemented by the computer device, wherein a temperature correction model is established in steps S1 and S2. The temperature correction model is used to correct the temperature sensed by the first and second ambient temperature sensors 1, 2 in subsequent steps.

In step S1, a database that contains multiple reference temperature sets is created. The database may be stored in buffer memory of the controller 4, the processing unit 6, a storage device (e.g., flash memory, a hard disk drive, a solid state drive, and so on; not shown) that is accessible by the controller 4 or the processing unit 6, or other computing devices, or can be stored in a form of parameters of a firmware program to be executed by the controller 4, and this disclosure is not limited in this respect. Each of the reference temperature sets is obtained under one of multiple predetermined conditions. Each of the predetermined conditions corresponds to one of various fan speed settings of the fan module 5. In particular, each of the reference temperature sets includes a first reference temperature value that was sensed by the first ambient temperature sensor 1 under the corresponding one of the predetermined conditions, a second reference temperature value that was sensed by the second ambient temperature sensor 2 under the corresponding one of the predetermined conditions, and a reference ambient temperature value that was sensed by a reference ambient temperature sensor (not shown) at a predetermined location relative to the computer device under the corresponding one of the predetermined conditions. It is noted that the reference ambient temperature value serves as the actual ambient temperature under the corresponding one of the predetermined conditions herein. In some embodiments, each of the predetermined conditions corresponds to at least one of a type, a number or a location of the at least one electronic component 31. In one example, each of the predetermined conditions may correspond to at least one of a USB type (e.g., USB 2.0, USB 3.0, or absence of USB ports), or a number of USB ports. In one example, each of the predetermined conditions may further correspond to other types of serial ports, such as a serial port type (RS-232-C, RS-422, RS-485, or absence of serial ports), a number of serial ports, or a location of serial ports.

Table 1 lists some exemplary reference temperature sets, where T_{R1} represents the first reference temperature value, T_{R2} represents the second reference temperature value, T_{RA} represents the reference ambient temperature value, and the fan speed is represented in a form of a percentage of a maximum rotational speed of the fan module 5.

TABLE 1

| USB type | USB 3.0 | | | | | |
|---|---|---|---|---|---|---|
| Port Quantity | 2 | | | | | |
| Fan speed | 20% | | | | | |
| T_{R1}(° C.) | 36.5 | 25% | 30% | 50% | 80% | 100% |
| T_{R2}(° C.) | 28.5 | 34.5 | 34 | 31 | 27.5 | 26 |
| T_{RA}(° C.) | 21 | 26.88 | 26.06 | 24.88 | 22.75 | 22.25 |

In step S2, the temperature correction model is established using the reference temperature sets by, for example, the controller 4, the processing unit 6 or other computing devices, and this disclosure is not limited in this respect. The temperature correction model may be established by, for example but not limited to, performing linear regression on the reference temperature sets, performing a machine learning algorithm on the reference temperature sets, etc., but this disclosure is not limited in this respect.

In this embodiment, the temperature correction model thus established is exemplified in a form of a linear function of:

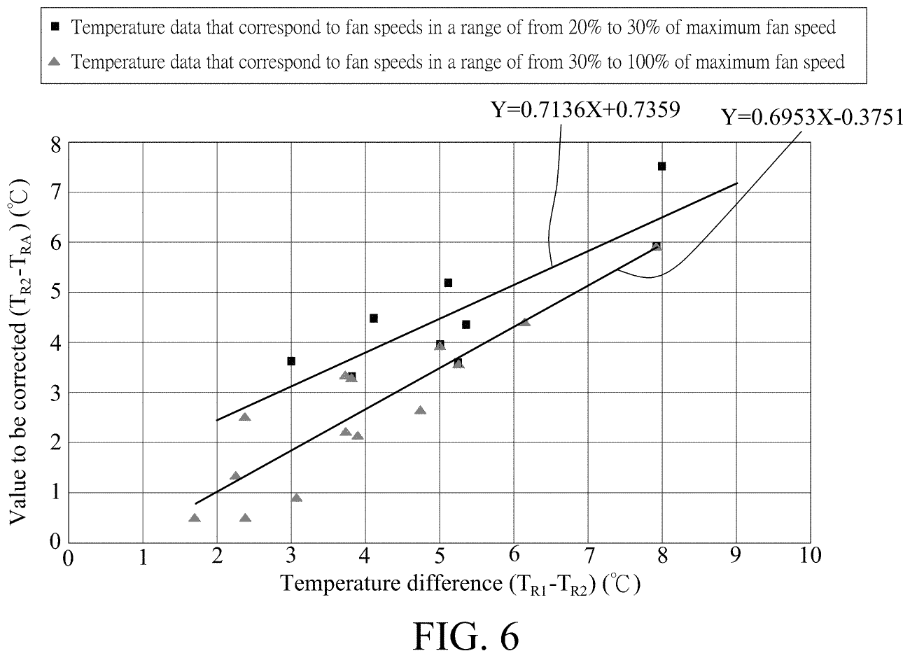

Y=T₂−Tₐ=a×X+b, where X=T₁−T₂ (1)

where T₁ represents the first ambient temperature value, T₂ represents the second ambient temperature value, Tₐ represents a corrected ambient temperature value, and a and b are parameters that are acquired based on the reference temperature sets (e.g., using linear regression, a machine learning algorithm, etc.). As exemplified in FIG. 6, the temperature correction model may include multiple functions respectively corresponding to different ranges of the fan speed of the fan module 5 (referred to as fan speed ranges hereinafter). In detail, the parameters a and b have multiple sets of values each corresponding to a respective one of the fan speed ranges. Each of the sets of the values of the parameters a and b is acquired based on some of the reference temperature sets that are obtained under some of the predetermined conditions which correspond to those of the various fan speed settings falling within the respective one of the fan speed ranges. In practice, the reference temperature sets may be divided into multiple groups that respectively correspond to the fan speed ranges. For each of the groups, the predetermined conditions under which the reference temperature sets in the group were obtained correspond to those of the various fan speed settings falling within the respective one of the fan speed ranges. Taking Table 1 as an example, the reference temperature values T_{R1}, T_{R2}, T_{RA} that respectively correspond to the fan speeds of 20%, 25% and 30% may be used to acquire a linear function F₁(X) that is used to correct temperatures that are sensed when the fan speed is in a range from 20% to 30% (noting that 20% is the minimum fan speed in this embodiment, but this disclosure is not limited in this respect), and the reference temperature values T_{R1}, T_{R2}, T_{RA} that respectively correspond to the fan speeds of 30%, 50%, 80% and 100% may be used to acquire a linear function F₂(X) that is used to correct temperatures that are sensed when the fan speed is in a range from 30% to 100%. When the temperature correction model is in use, either the linear function F₁(x) or the linear function F₂(x) can be selectively used to correct the sensed temperature value when the fan speed is 30% of the maximum fan speed. In FIG. 6, the parameters a and b for the linear function F₁(X) are acquired, based on the given data that are represented by square points, as being 0.7136 and 0.7359, respectively, and the parameters a and b for the linear function F₂(X) are acquired, based on the given data that are represented by triangular points, as being 0.6953 and −0.3751, respectively. In such a case, the temperature correction model may be represented by:

N=f(ΔT, RPM), where ΔT=T₁−T₂ (2)

where RPM represents a current fan speed of the fan module 5, and N represents a correction value, which is equal to the value Y of a linear function that corresponds to one of the fan speed ranges within which the current fan speed falls.

After the temperature correction model is established, steps for correcting the sensed temperature includes steps A to E.

In step A, the first ambient temperature sensor 1 senses a nearby temperature, and the second ambient temperature sensor 2 senses a nearby temperature.

In step B, the controller 4 reads the temperatures sensed by the first ambient temperature sensor 1 to generate the first ambient temperature value, reads the temperatures sensed by the second ambient temperature sensor 2 to generate the second ambient temperature value, and determines whether a temperature difference between the first ambient temperature value and the second ambient temperature value is greater than the predetermined threshold value. Upon determining that the temperature difference is greater than the predetermined threshold value, the flow goes to step C, where the controller 4 performs a temperature correction procedure on one of the first ambient temperature value and the second ambient temperature value. Otherwise, the flow goes to step D. In this embodiment, the second ambient temperature sensor 2, while being spaced apart from the circuit board 32, is electrically connected to the circuit board 32, and the circuit board 32 is electrically connected to the controller 4, so the controller 4 can read the temperatures sensed by the first and second ambient temperature sensors 1, 2 to generate the first ambient temperature value and the second ambient temperature value. The electric connection between the second ambient temperature sensor 2 and the circuit board 32 may be realized via cables, wires, connectors or a combination thereof.

In step C, the controller 4 uses the temperature correction model to calculate a corrected ambient temperature value based on a current fan speed of the fan module 5, the temperature difference, and at least one of the first ambient temperature value or the second ambient temperature value. In detail, the controller 4 uses the temperature correction model to obtain the correction value N. Then, the controller 4 obtains the corrected ambient temperature value as, for example, Tₐ=T2−N in this embodiment.

In step D, the controller 4 selects one of the first ambient temperature value and the second ambient temperature value for use in step E. The selecting rule may be predefined by a user. For example, the selected one of the first ambient temperature value and the second ambient temperature value (referred to as selected ambient temperature value) may be a smaller one of the first ambient temperature value and the second ambient temperature value, a greater one of the first ambient temperature value and the second ambient temperature value, or a predetermined one of the first ambient temperature value and the second ambient temperature value, but this disclosure is not limited in this respect.

In step E, the controller 4 adjusts the current fan speed based on the corrected ambient temperature value obtained in step C or the selected ambient temperature value obtained in step D.

It is noted that the controller 4 may perform the above steps to determine whether the sensed ambient temperature needs to be corrected and/or refresh the corrected value N at regular intervals, so most of the time, only one of the first and second ambient temperature sensors 1, 2 may be activated to perform temperature monitoring, and the resultant power consumption can thus be reduced.

Accordingly, in the embodiment according to this disclosure, the controller 4 can detect whether the peripheral device module 3 is connected to a peripheral device 7 (e.g., whether a USB flash drive is inserted into any one of the USB ports 31 and thus generates heat) by determining whether the temperature difference between the temperature values sensed by the first and second ambient temperature sensors 1, 2 is greater than the predetermined threshold value. Upon determining that the peripheral device module 3 is connected to a peripheral device 7 (i.e., the temperature difference is greater than the predetermined threshold value), the controller 4 performs temperature correction on one of the first ambient temperature value and the second ambient temperature value, so as to obtain the corrected ambient temperature value which is relatively more accurate. As a result, the controller 4 can mitigate the effects brought about by connection between the peripheral device 7 and the peripheral device module 3 that raises the temperature of the circuit board 32, which may cause unnecessary increase of the current fan speed due to, and may thus control the current fan speed of the fan module 5 more accurately based on the corrected ambient temperature value, thereby avoiding unnecessary power consumption.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A temperature correction method, implemented by a computer device that includes a first ambient temperature sensor, a second ambient temperature sensor, and a fan module disposed to reduce a temperature within the computer device, comprising steps of:
A) by the first ambient temperature sensor, sensing a temperature nearby the first ambient temperature sensor;
B) by the second ambient temperature sensor that is spaced apart from the first ambient temperature sensor, sensing a temperature nearby the second ambient temperature sensor;
C) by a controller of the computer device, reading the temperature sensed by the first ambient temperature sensor to generate a first ambient temperature value, reading the temperature sensed by the second ambient temperature sensor to generate a second ambient temperature value, and determining whether a temperature difference between the first ambient temperature value and the second ambient temperature value is greater than a predetermined threshold value; and
D) by the controller, upon determining that the temperature difference is greater than the predetermined threshold value, using a temperature correction model to calculate a corrected ambient temperature value based on a current fan speed of the fan module, the temperature difference, and at least one of the first ambient temperature value or the second ambient temperature value.

2. The temperature correction method of claim 1, wherein step D) further includes adjusting the current fan speed of the fan module based on the corrected ambient temperature value.

3. The temperature correction method of claim 2, further comprising a step of:
E) by the controller, upon determining that the temperature difference is not greater than the predetermined threshold value, adjusting the current fan speed of the fan module based on one of the first ambient temperature value and the second ambient temperature value.

4. The temperature correction method of claim 1, further comprising a step of using multiple reference temperature sets to establish the temperature correction model;
wherein each of the reference temperature sets is obtained under a corresponding one of multiple predetermined conditions, each of the predetermined conditions corresponding to one of various fan speed settings of the fan module;
wherein each of the reference temperature sets includes:
a first reference temperature value that was measured by the first ambient temperature sensor under the corresponding one of the predetermined conditions;
a second reference temperature value that was measured by the second ambient temperature sensor under the corresponding one of the predetermined conditions; and
a reference ambient temperature value that was measured by a reference ambient temperature sensor at a predetermined location relative to the computer device under the corresponding one of the predetermined conditions.

5. The temperature correction method of claim 4, wherein the temperature correction model is established using linear regression.

6. The temperature correction method of claim 4, wherein the temperature correction model is related to an equation of:
Y=T₂−Tₐ=a×X+b, where X=T₁−T₂
where T₁ represents the first ambient temperature value, T₂ represents the second ambient temperature value, Tₐ represents the corrected ambient temperature value, and a and b are parameters that are acquired based on the reference temperature sets.

7. The temperature correction method of claim 6, wherein the parameters a and b have multiple sets of values each corresponding to a respective range of a fan speed of the fan module; and
wherein each of the sets of the values of the parameters a and b is acquired based on some of the reference temperature sets that are obtained under some of the predetermined conditions which correspond to those of the various fan speed settings falling within the respective range of the fan speed of the fan module.

8. The temperature correction method of claim 4, wherein the reference temperature sets are divided into multiple groups that respectively correspond to a plurality of fan speed ranges;
wherein, for each of the groups, the predetermined conditions under which the reference temperature sets in the group are obtained correspond to those of the various fan speed settings falling within the respective one of the fan speed ranges.

9. The temperature correction method of claim 4, wherein the computer device includes an electronic component that generates heat during operation, and that is closer to the first ambient temperature sensor than the electronic component is to the second ambient temperature sensor, and each of the predetermined conditions corresponds to at least one of a type, a number or a location of the electronic component.

10. The temperature correction method of claim 9, wherein the electronic component includes at least one of a universal serial bus (USB) port, a serial port, or a digital visual interface (DVI) port.

11. A computer device, comprising:
a first ambient temperature sensor that is configured to sense a temperature nearby said first ambient temperature sensor;
a second ambient temperature sensor that is spaced apart from said first ambient temperature sensor, and that is configured to sense a temperature nearby said second ambient temperature sensor;
a controller that is electrically coupled to said first ambient temperature sensor for reading the temperature sensed thereby to generate a first ambient temperature value, that is electrically coupled to said second ambient temperature sensor for reading the temperature sensed thereby to generate a second ambient temperature value, and that is configured to determine whether a temperature difference between the first ambient temperature value and the second ambient temperature value is greater than a predetermined threshold value; and
a fan module that is electrically coupled to said controller and that is disposed to reduce a temperature within the computer device;
wherein said controller is further configured to, upon determining that the temperature difference is greater than the predetermined threshold value, use a temperature correction model to calculate a corrected ambient temperature value based on a current fan speed of said fan module, the temperature difference, and at least one of the first ambient temperature value or the second ambient temperature value.

12. The computer device of claim 11, wherein said controller is further configured to adjust the current fan speed of said fan module based on the corrected ambient temperature value upon determining that the temperature difference is greater than the predetermined threshold value.

13. The computer device of claim 12, wherein said controller is further configured to, upon determining that the temperature difference is not greater than the predetermined threshold value, adjust the current fan speed of said fan module based on one of the first ambient temperature value and the second ambient temperature value.

14. The computer device of claim 11, wherein the temperature correction model is established using multiple reference temperature sets;
wherein each of the reference temperature sets is obtained under a corresponding one of multiple predetermined conditions, each of the predetermined conditions corresponding to one of various fan speed settings of said fan module;
wherein each of the reference temperature sets includes:
a first reference temperature value that was measured by said first ambient temperature sensor under the corresponding one of the predetermined conditions;
a second reference temperature value that was measured by said second ambient temperature sensor under the corresponding one of the predetermined conditions; and
a reference ambient temperature value that was measured by a reference ambient temperature sensor at a predetermined location relative to said computer device under the corresponding one of the predetermined conditions.

15. The computer device of claim 14, wherein the temperature correction model is established using linear regression.

16. The computer device of claim 4, wherein the temperature correction model is related to an equation of:
Y=T₂Tₐ=a×X+b, where X=T₁−T₂
where T₁ represents the first ambient temperature value, T₂ represents the second ambient temperature value, Tₐ represents the corrected ambient temperature value, and a and b are parameters that are acquired based on the reference temperature sets.

17. The computer device of claim 16, wherein the parameters a and b have multiple sets of values each corresponding to a respective range of a fan speed of said fan module; and
wherein each of the sets of the values of the parameters a and b is acquired based on some of the reference temperature sets that are obtained under some of the predetermined conditions which correspond to those of the various fan speed settings falling within the respective range of the fan speed of said fan module.

18. The computer device of claim 14, wherein the reference temperature sets are divided into multiple groups that respectively correspond to a plurality of fan speed ranges;
wherein, for each of the groups, the predetermined conditions under which the reference temperature sets in the group are obtained correspond to those of the various fan speed settings falling within the respective one of the fan speed ranges.

19. The computer device of claim 14, further comprising an electronic component that generates heat during operation and that is closer to said first ambient temperature sensor than said electronic component is to said second ambient temperature sensor, wherein each of the predetermined conditions corresponds to at least one of a type, a number or a location of said electronic component.

20. The computer device of claim 11, further comprising a circuit board on which said electronic component and said first ambient temperature sensor are located, and a casing that accommodates said circuit board therein, wherein said second ambient temperature sensor is mounted to said casing.
